(19) United States
(12) Patent Application Publication
(10) Pub. No.: US 2022/0406605 A1
(43) Pub. Date: Dec. 22, 2022

(54) SUBSTRATE LIQUID PROCESSING METHOD AND SUBSTRATE LIQUID PROCESSING APPARATUS

(71) Applicant: Tokyo Electron Limited, Tokyo (JP)

(72) Inventor: Yuichiro Inatomi, Kikuchi-gun, Kumamoto (JP)

(21) Appl. No.: 17/755,405

(22) PCT Filed: Oct. 16, 2020
(86) PCT No.: PCT/JP2020/039018

§ 371 Date: Apr. 28, 2022

(30) Foreign Application Priority Data
Oct. 30, 2019 (JP) 2019-197924

(51) Int. Cl. H01L 21/288; C23C 18/16; C23C 16/44

(52) U.S. Cl. CPC H01L 21/288; C23C 18/1676; C23C 18/1632; C23C 16/4412; H01L 21/6715

(57) ABSTRACT

A substrate liquid processing method includes holding a substrate W with a substrate holder 52; supplying a plating liquid L1 onto a top surface of the substrate; covering the substrate with a cover body 6 disposed above the held substrate, the cover body having a ceiling portion 61; and heating the plating liquid on the substrate by a heating unit 63 provided in either one of at least the cover body and the substrate holder in a state that the substrate is covered with the cover body. A gas exhausting operation of pushing out a reaction gas staying between the cover body and the substrate by moving either one of at least the cover body and the substrate holder vertically is performed in the heating of the plating liquid.

### TECHNICAL FIELD

The various aspects and embodiments described herein pertain generally to a substrate liquid processing method and a substrate liquid processing apparatus.

### BACKGROUND

Patent Document 1 describes a substrate liquid processing apparatus configured to perform electroless plating on a substrate (wafer) by using a processing liquid composed of a plating liquid.

### PRIOR ART DOCUMENT

Patent Document 1: Japanese Patent Laid-open Publication No. 2018-003097

### DISCLOSURE OF THE INVENTION

### Problems to be Solved by the Invention

Exemplary embodiments provide a technique enabling to improve uniformity of a plating film within a surface of a substrate in an electroless plating processing.

### Means for Solving the Problems

In an exemplary embodiment, there is provided a substrate liquid processing method of performing a liquid processing on a substrate by supplying a plating liquid onto the substrate. The substrate liquid processing method includes holding the substrate with a substrate holder; supplying the plating liquid onto a top surface of the substrate; covering the substrate with a cover body disposed above the held substrate, the cover body having a ceiling portion; and heating the plating liquid on the substrate by a heating unit provided in either one of at least the cover body and the substrate holder, in a state that the substrate is covered with the cover body. A gas exhausting operation of pushing out a reaction gas staying between the cover body and the substrate by moving either one of at least the cover body and the substrate holder vertically is performed in the heating of the plating liquid.

### Effect of the Invention

According to the exemplary embodiment, it is possible to improve the uniformity of the plating film within the surface of the substrate in the electroless plating processing.

### BRIEF DESCRIPTION OF THE DRAWINGS

FIG. 1 is a schematic diagram illustrating a configuration of a plating apparatus as an example of a substrate liquid processing apparatus according to an exemplary embodiment.

FIG. 2 is a cross sectional view illustrating a configuration of a plating device shown in FIG. 1.

FIG. 3 is a plan cross sectional view illustrating a nozzle arm and a cover body of FIG. 2.

FIG. 4 is a flowchart illustrating a plating processing on a substrate in the plating apparatus in FIG. 1.

FIG. 5A is a diagram for describing a substrate holding process of FIG. 4.

FIG. 5B is a diagram for describing a plating liquid accumulating process of FIG. 4.

FIG. 5C is a diagram for describing a plating liquid heating process of FIG. 4.

FIG. 5D is a diagram for describing a change of a descending speed of the cover body of FIG. 3.

FIG. 5E is a diagram for describing a heating process of FIG. 4.

FIG. 5F is a diagram for describing a substrate drying process of FIG. 4.

### DETAILED DESCRIPTION

Hereinafter, an exemplary embodiment of the present disclosure will be described with reference to the accompanying drawings.

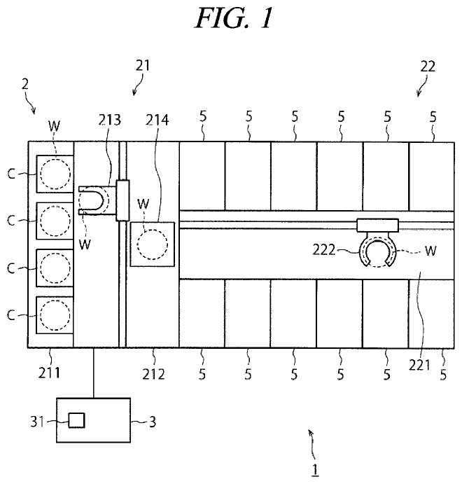

First, referring to FIG. 1, a configuration of a substrate liquid processing apparatus according to the exemplary embodiment of the present disclosure will be explained. FIG. 1 is a schematic diagram illustrating a configuration of a plating apparatus as an example of the substrate liquid processing apparatus according to the exemplary embodiment of the present disclosure. Here, the plating apparatus is an apparatus configured to perform a plating processing (liquid processing) on a substrate W by supplying a plating liquid L1 (processing liquid) onto the substrate W.

As shown in FIG. 1, a plating apparatus 1 according to the exemplary embodiment of the present disclosure includes a plating unit 2, and a controller 3 configured to control an operation of the plating unit 2.

The plating unit 2 is configured to perform various processings on the substrate (wafer) W. The processings performed by the plating unit 2 will be described later.

The controller 3 is, for example, a computer, and includes an operation controller and a storage. The operation controller is configured as, for example, a CPU (Central Processing Unit) and configured to control the operation of the plating unit 2 by reading and executing a program stored in the storage. The storage is configured as a storage device such as a RAM (Random Access Memory), a ROM (Read Only Memory) or a hard disk, and stores therein the program for controlling various processings performed in the plating unit 2. Further, the program may be recorded in a computer-readable recording medium 31, or may be installed from the recording medium 31 to the storage. The computer-readable recording medium 31 may be, for example, a hard disc (HD), a flexible disc (FD), a compact disc (CD), a magneto optical disc (MO), or a memory card. The recording medium 31 stores therein a program that, when executed by a computer for controlling an operation of the plating apparatus 1, causes the computer to control the plating apparatus 1 to perform a plating method to be described later.

Referring to FIG. 1, a configuration of the plating unit 2 will be elaborated.

The plating unit 2 is equipped with a carry-in/out station 21; and a processing station 22 provided adjacent to the carry-in/out station 21.

The carry-in/out station 21 includes a placing section 211 and a transfer section 212 provided adjacent to the placing section 211.

In the placing section 211, a plurality of transfer containers (hereinafter, referred to as “carriers C”) each of which accommodates therein a plurality of substrates W horizontally is placed.

The transfer section 212 includes a transfer mechanism 213 and a delivery unit 214. The transfer mechanism 213 includes a holding mechanism configured to hold a substrate W, and is configured to be movable horizontally and vertically and pivotable around a vertical axis.

The processing station 22 includes a plurality of plating devices 5. In the present exemplary embodiment, the number of plating devices 5 provided in the processing station 22 is two or more, but may be one. The plating devices 5 are arranged on both sides of a transfer path 221 which is extended in a predetermined direction (on both sides in a direction perpendicular to a moving direction of a transfer mechanism 222 to be described later).

The transfer path 221 is provided with the transfer mechanism 222. The transfer mechanism 222 includes a holding mechanism configured to hold a substrate W, and is configured to be movable horizontally and vertically and pivotable around a vertical axis.

In the plating unit 2, the transfer mechanism 213 of the carry-in/out station 21 is configured to transfer the substrate W between the carrier C and the delivery unit 214. Specifically, the transfer mechanism 213 takes out the substrate W from the carrier C placed in the placing section 211, and then, places the substrate W in the delivery unit 214. Further, the transfer mechanism 213 takes out the substrate W which is placed in the delivery unit 214 by the transfer mechanism 222 of the processing station 22, and then, accommodates the substrate W in the carrier C of the placing section 211.

In the plating unit 2, the transfer mechanism 222 of the processing station 22 is configured to transfer the substrate W between the delivery unit 214 and the plating device 5 and between the plating device 5 and the delivery unit 214. Specifically, the transfer mechanism 222 takes out the substrate W placed in the delivery unit 214 and carries the substrate W into the plating device 5. Further, the transfer mechanism 222 takes out the substrate W from the plating device 5 and places the substrate W in the delivery unit 214.

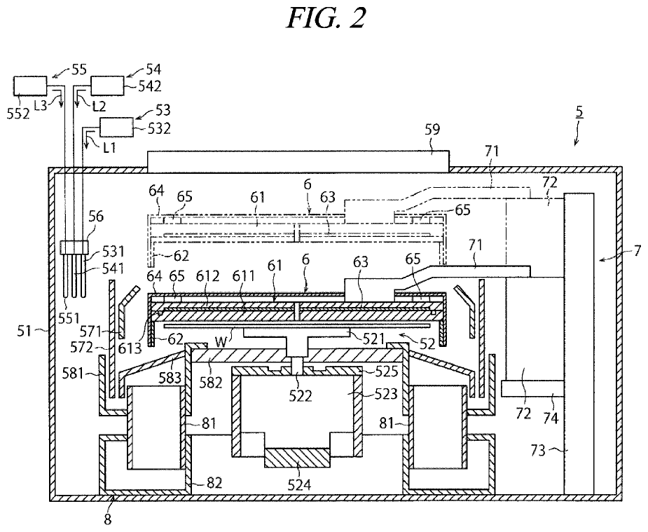

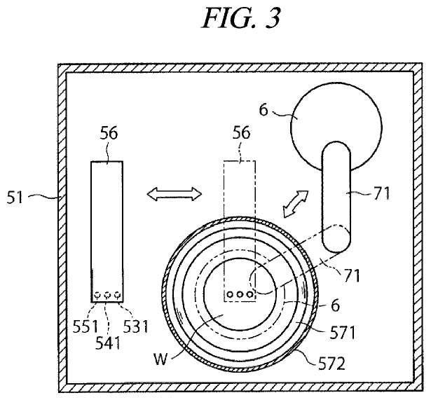

Now, a configuration of the plating device 5 will be described with reference to FIG. 2 and FIG. 3. FIG. 2 is a schematic cross sectional view illustrating the configuration of the plating device 5.

The plating device 5 is configured to perform a liquid processing including an electroless plating processing. This plating device 5 includes a chamber 51; a substrate holder 52 disposed within the chamber 51 and configured to hold the substrate W horizontally; and a plating liquid supply 53 (processing liquid supply) configured to supply a plating liquid L1 (processing liquid) onto a top surface of the substrate W held by the substrate holder 52. In the present exemplary embodiment, the substrate holder 52 has a chuck member 521 configured to vacuum-attract a bottom surface (rear surface) of the substrate W. This chuck member 521 is of a so-called vacuum chuck type. Without being limited thereto, however, the chuck member 521 may be of a so-called mechanical chuck type configured to grip an edge portion of the substrate W with a chuck mechanism or the like. Furthermore, the substrate holder 52 may be equipped with a substrate holder elevating mechanism (not shown) configured to operate the substrate holder 52 in an up-and-down direction. The substrate holder elevating mechanism may be implemented by a cylinder or an actuator including a motor and a ball screw.

The substrate holder 52 is connected to a rotation motor 523 (rotational driving unit) via a rotation shaft 522. When the rotation motor 523 is driven, the substrate holder 52 is rotated along with the substrate W thereon. The rotation motor 523 is supported at a base 524 fixed to the chamber 51.

As depicted in FIG. 2, the plating liquid supply 53 includes a plating liquid nozzle 531 (processing liquid nozzle) configured to discharge (supply) the plating liquid L1 onto the substrate W held by the substrate holder 52, and a plating liquid source 532 configured to supply the plating liquid L1 to the plating liquid nozzle 531. Here, the plating liquid source 532 is configured to supply the plating liquid L1 heated or temperature-controlled to a predetermined temperature to the plating liquid nozzle 531. The temperature of the plating liquid L1 when it is discharged from the plating liquid nozzle 531 is in the range of, e.g., 55° C. to 75° C., and, more desirably, in the range of 60° C. to 70° C. The plating liquid nozzle 531 is configured to be movable by being held by a nozzle arm 56.

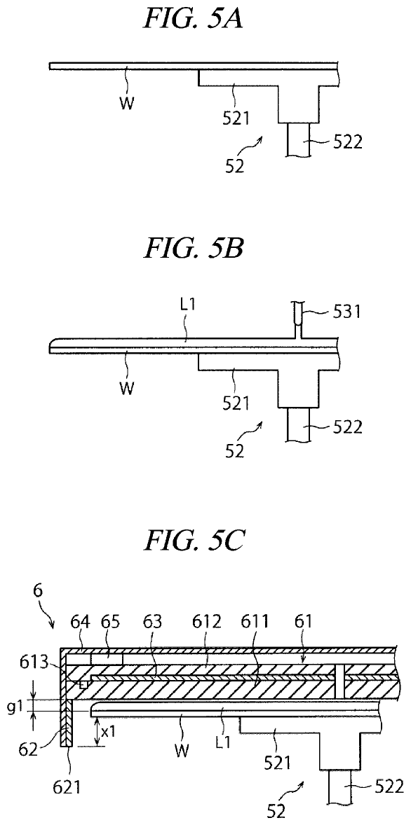

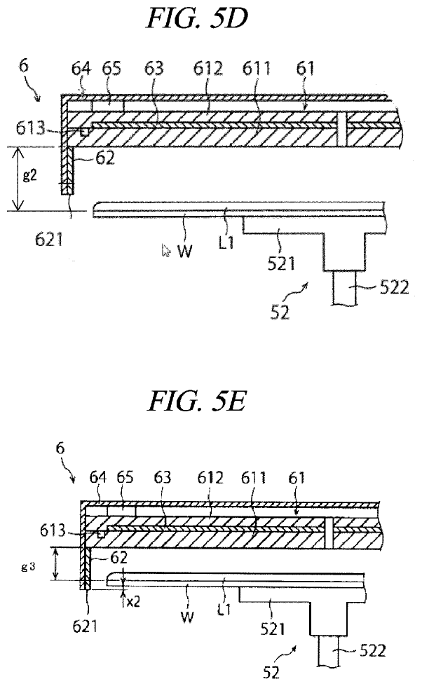

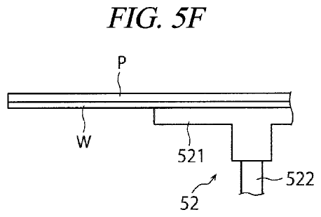

The plating liquid L1 is an autocatalytic (reduction) plating liquid for electroless plating. The plating liquid L1 contains a metal ion such as a cobalt (Co) ion, a nickel (Ni) ion, a tungsten (W) ion, a copper (Cu) ion, a palladium (Pd) ion or a gold (Au) ion, and a reducing agent such as hypophosphorous acid or dimethylamine borane. The plating liquid L1 may further contain an additive or the like. A plating film P (metal film, see FIG. 5F) formed by the plating processing with the plating liquid L1 may be, for example, CoWB, CoB, CoWP, CoWBP, NiWB, NiB, NiWP, NiWBP, or the like.

The plating device 5 according to the present exemplary embodiment further includes, as other processing liquid supplies, a cleaning liquid supply 54 configured to supply a cleaning liquid L2 onto the top surface of the substrate W held by the substrate holder 52, and a rinse liquid supply 55 configured to supply a rinse liquid L3 onto the top surface of the substrate W.

The cleaning liquid supply 54 is equipped with a cleaning liquid nozzle 541 configured to discharge the cleaning liquid L2 onto the substrate W held by the substrate holder 52, and a cleaning liquid source 542 configured to supply the cleaning liquid L2 to the cleaning liquid nozzle 541. Examples of the cleaning liquid L2 may include an organic acid such as a formic acid, a malic acid, a succinic acid, a citric acid or a malonic acid, or a hydrofluoric acid (DHF) (aqueous solution of hydrogen fluoride) diluted to the extent that it does not corrode a plating target surface of the substrate W. The cleaning liquid nozzle 541 is held by the nozzle arm 56 and configured to be movable along with the plating liquid nozzle 531.

The rinse liquid supply 55 is equipped with a rinse liquid nozzle 551 configured to supply the rinse liquid L3 onto the substrate W held by the substrate holder 52, and a rinse liquid source 552 configured to supply the rinse liquid L3 to the rinse liquid nozzle 551. The rinse liquid nozzle 551 is held by the nozzle arm 56 and configured to be movable along with the plating liquid nozzle 531 and the cleaning liquid nozzle 541. Examples of the rinse liquid L3 may include pure water (deionized water) or the like.

A non-illustrated nozzle moving mechanism is connected to the nozzle arm 56 that holds the plating liquid nozzle 531, the cleaning liquid nozzle 541, and the rinse liquid nozzle 551 described above. This nozzle moving mechanism moves the nozzle arm 56 in a horizontal direction and an up-and-down direction. More specifically, as shown in FIG. 3, the nozzle arm 56 is moved between a discharge position (a position indicated by a dashed double-dotted line in FIG. 3) and a retreat position (a position indicated by a solid line in FIG. 3) retreated from the discharge position by the nozzle moving mechanism. The discharge position is a position at which the processing liquid (the plating liquid L1, the cleaning liquid L2, or the rinse liquid L3) is discharged to the substrate W. Here, the discharge position is not particularly limited as long as the processing liquid can be supplied to a certain position on the top surface of the substrate W. By way of example, it is desirable that the discharge position is set to be a position where the processing liquid can be supplied to a center of the substrate W. The discharge position may be set differently between the cases of supplying the plating liquid L1, supplying the cleaning liquid L2 and supplying the rinse liquid L3 onto the substrate W. The retreat position is a position within the chamber 51 which is not overlapped with the substrate W when viewed from above, and is a position far from the discharge position. When the nozzle arm 56 is placed at the retreat position, interference between the nozzle arm 56 and the cover body 6 being moved is avoided.

A cup 571 is disposed around the substrate holder 52. The cup 571 is formed into a ring shape when viewed from above, and configured to receive the processing liquid scattered from the substrate W when the substrate W is being rotated and configured to guide the received processing liquid to a drain duct 581 to be described later. An atmosphere blocking cover 572 is provided at an outer peripheral side of the cup 571 and configured to suppress diffusion of the ambient atmosphere around the substrate W in the chamber 51. The atmosphere blocking cover 572 is formed into a vertically extending cylindrical shape and has an open top. The cover body 6 to be descried later can be inserted into the atmosphere blocking cover 572 from above.

The drain duct 581 is provided under the cup 571. The drain duct 581 is formed into a ring shape when viewed from above, and serves to drain the processing liquid falling down after being received by the cup 571 and the processing liquid directly falling down from the vicinity of the substrate W. An inner cover 582 is provided at an inner periphery side of the drain duct 581. The inner cover 582 is disposed above the cooling plate 525, and serves to suppress diffusion of the processing liquid and the atmosphere around the substrate W. A guide member 583 configured to guide the processing liquid into the drain duct 581 is provided above an exhaust pipe 81 to be described later. Due to the presence of this guide member 583, the processing liquid falling from above the exhaust pipe 81 is suppressed from entering the exhaust pipe 81, and is received into the drain duct 581.

The substrate W held by the substrate holder 52 is covered by the cover body 6. The cover body 6 has a ceiling portion 61 and a sidewall portion 62 extending downwards from the ceiling portion 61. When the cover body 6 is located at a first gap position or a second gap position to be described later, the ceiling portion 61 is disposed above the substrate W held by the substrate holding unit 52, facing the substrate W with a relatively small gap therebetween.

The ceiling member 61 includes a first ceiling plate 611 and a second ceiling plate 612 provided on the first ceiling plate 611. A heater 63 (heating unit) to be described later is interposed between the first ceiling plate 611 and the second ceiling plate 612. The first ceiling plate 611 and the second ceiling plate 612 are configured to seal the heater 63 such that the heater 63 is not brought into contact with the processing liquid such as the plating liquid L1. More specifically, a seal ring 613 is provided at an outer peripheral side of the heater 63 between the first ceiling plate 611 and the second ceiling plate 612, and the heater 63 is sealed by the seal ring 613. Desirably, the first ceiling plate 611 and the second ceiling plate 612 have corrosion resistance against the processing liquid such as the plating liquid L1, and may be made of, for example, an aluminum alloy. Further, to improve the corrosion resistance, the first ceiling plate 611, the second ceiling plate 612 and the sidewall member 62 may be coated with Teflon (registered trademark).

The cover body 6 is connected to a cover body moving mechanism 7 via a cover body arm 71. The cover body moving mechanism 7 is configured to move the cover body 6 horizontally and vertically. More specifically, the cover body moving mechanism 7 is equipped with a rotation motor 72 configured to move the cover body 6 horizontally and a cylinder 73 (gap adjusting unit) configured to move the cover body 6 vertically. The rotation motor 72 is provided on a supporting plate 74 configured to be movable up and down with respect to the cylinder 73. Here, instead of the cylinder 73, an actuator (not shown) including a motor and a ball screw may be used.

As depicted in FIG. 3, the rotation motor 72 of the cover body moving mechanism 7 is configured to move the cover body 6 between an upper position (a position indicated by a dashed double-dotted line in FIG. 3) located above the substrate W held by the substrate holder 52 and a retreat position (a position indicated by a solid line in FIG. 3) retreated from the upper position. The upper position is a position facing the substrate W, which is held by the substrate holder 52, with a relatively large gap therebetween and overlapping with the substrate W when viewed from above. The retreat position is a position within the chamber 51 which does not overlap with the substrate W when viewed from above. When the cover body 6 is located at the retreat position, it is possible to avoid the interference between the nozzle arm 56 being moved and the cover body 6. A rotation axis of the rotation motor 72 is vertically extended, and the cover body 6 is configured to be pivotable horizontally between the upper position and the retreat position.

As shown in FIG. 2, the cylinder 73 of the cover body moving mechanism 7 moves the cover body 6 in an up-and-down direction to adjust a gap between the first ceiling plate 611 of the ceiling portion 61 and the substrate W on which the plating liquid L1 is supplied. To be more specific, the cylinder 73 locates the cover body 6 at the first gap position (see FIG. 5C), the second gap position (see FIG. 5D), or the aforementioned upper position (the position indicted by the dashed double-dotted line in FIG. 2).

At the first gap position, the gap between the substrate W and the first ceiling plate 611 becomes a first gap g1 (see FIG. 5C) which is the smallest, so the first ceiling plate 611 comes closest to the substrate W. In this case, in order to suppress contamination and loss of the plating liquid L1 or to suppress generation of air bubbles in the plating liquid L1, it is desirable to set the first gap g1 such that the first ceiling plate 611 does not come into contact with the plating liquid L1 on the substrate W.

At the second gap position, the gap between the substrate W and the first ceiling plate 611 becomes a second gap g2 (see FIG. 5D) which is larger than the first gap g1. Accordingly, the cover body 6 is located at a position above the first gap position.

At the upper position, the gap between the substrate W and the first ceiling plate 611 becomes larger than the second gap g2, and the cover body 6 is located at a position above the second gap position. That is, the upper position is set to be a height position where the cover body 6 can be suppressed from interfering with an ambient structure such as the cup 571 or the atmosphere blocking cover 572 when the cover body 6 is rotated horizontally.

The cover body 6 is configured to be moved between the first gap position, the second gap position, and the upper position by the cylinder 73. That is, the cylinder 73 is configured to be capable of adjusting the gap between the substrate W and the first ceiling plate 611 to the first gap g1 or the second gap g2.

As shown in FIG. 2, the sidewall portion 62 of the cover body 6 extends downwards from an edge of the first top plate 611 of the ceiling portion 61, and is located near an outer periphery of the substrate W when the plating liquid L1 on the substrate W is heated (that is, when the cover body 6 is positioned at the first gap position or the second gap position). When the cover body 6 is located at the first gap position, a lower end 621 of the sidewall portion 62 is located at a position lower than the substrate W, as illustrated in FIG. 5C. In this case, it is desirable that a distance x1 between the lower end 621 of the sidewall portion 62 and the bottom surface of the substrate W in the up-and-down direction is set to be, e.g., 10 mm to 30 mm.

As depicted in FIG. 2, the heater 63 is provided in the ceiling portion 61 of the cover body 6. The heater 63 heats the processing liquid (appropriately, the plating liquid L1) on the substrate W when the cover body 6 is located at the first gap position or the second gap position. In the present exemplary embodiment, the heater 63 is embedded between the first ceiling plate 611 and the second ceiling plate 612 of the cover body 6. This heater 63 is sealed as described above so that it is suppressed from coming into contact with the processing liquid such as the plating liquid L1.

The ceiling member 61 and the sidewall member 62 of the cover body 6 are covered by a cover body cover 64. The cover body cover 64 is provided on the second ceiling plate 612 of the cover body 6 with supporting members 65 therebetween. That is, a plurality of supporting members 65 protruded upwards from an upper surface of the second ceiling plate 612 is provided on the second ceiling plate 612, and the cover body cover 64 is placed on these supporting members 65. The cover body cover 64 is configured to be movable horizontally and vertically along with the cover body 6. Further, it is desirable that the cover body cover 64 has higher thermal insulation property than the ceiling member 61 and the sidewall member 62 to suppress a leakage of the heat within the cover body 6 to the vicinity thereof. For example, desirably, the cover body cover 64 may be made of a resin material. More desirably, the resin material has thermal resistance.

As shown in FIG. 2, a fan filter unit 59 (gas supply) configured to supply clean air (gas) around the cover body 6 is provided at a top portion of the chamber 51. The fan filter unit 59 supplies air into the chamber 51 (particularly, into the atmosphere blocking cover 572), and the supplied air flows toward an exhaust line 81 to be described later. A downflow of this air is formed around the cover body 6, and a gas vaporized from the processing liquid such as the plating liquid L1 flows toward the exhaust line 81 along with this downflow. Accordingly, it is possible to suppress the rise and diffusion of the gas vaporized from the processing liquid within the chamber 51.

In the present exemplary embodiment, a supply amount of the gas from the fan filter unit 59 when the plating liquid L1 on the substrate W is heated by the heater 63 is set to be smaller than a supply amount of the gas from the fan filter unit 59 when the plating liquid L1 is supplied onto the substrate W. More specifically, when the cover body 6 is located at the first gap position, a supply amount of the air from the fan filter unit 59 is set to be smaller than a supply amount of the air when the cover body 6 is located at the retreat position or the upper position.

The gas supplied from the fan filter unit 59 is exhausted by a gas exhaust mechanism 8. As illustrated in FIG. 2, the gas exhaust mechanism 8 is equipped with two exhaust lines 81 provided under the cup 571 and an exhaust duct 82 provided under the drain duct 581. The two exhaust lines 81 penetrate a bottom portion of the drain duct 581 and individually communicate with the exhaust duct 82. The exhaust duct 82 is formed into a substantially semi-circular ring shape when viewed from above. In the present exemplary embodiment, the single exhaust duct 82 is provided under the drain duct 581 and the two exhaust lines 81 communicate with this exhaust duct 82.

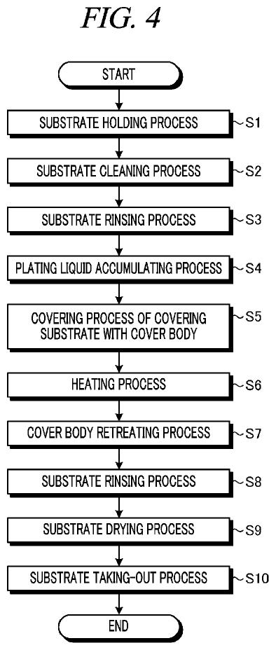

Now, an operation of the present exemplary embodiment having the above-described configuration will be explained with reference to FIG. 4 and FIG. 5A to FIG. 5F. Here, as an example of the substrate liquid processing method, a plating method using the plating apparatus 1 will be discussed.

The plating method performed by the plating apparatus 1 includes a plating processing on the substrate W. The plating processing is performed by the plating device 5. An operation of the plating device 5 to be described below is controlled by a control signal from the controller 3.

[Substrate Holding Process]

First, the substrate W is carried into the plating device 5, and the carried-into substrate W is held by the substrate holder 52, as illustrated in FIG. 5A (process 51). Here, the bottom surface of the substrate W is vacuum-attracted, and the substrate W is horizontally held by the substrate holder 52.

[Substrate Cleaning Process]

Then, the substrate W held by the substrate holder 52 is subjected to a cleaning processing (process S2). In this case, the rotation motor 523 is first driven to rotate the substrate W at a preset rotational speed. Subsequently, the nozzle arm 56 located at the retreat position (the position indicated by the solid line in FIG. 3) is moved to the discharge position (the position indicated by the dashed double-dotted line in FIG. 3). Thereafter, the cleaning liquid L2 is supplied from the cleaning liquid nozzle 541 onto the substrate W being rotated, so that the front surface of the substrate W is cleaned. Thus, the deposit or the like adhering to the substrate W is removed from the substrate W. The cleaning liquid L2 supplied onto the substrate W is drained into the drain duct 581.

[Substrate Rinsing Process]

Thereafter, the cleaned substrate W is subjected to a rinsing processing (process S3). In this case, the rinse liquid L3 is supplied from the rinse liquid nozzle 551 onto the substrate W being rotated, so that the front surface of the substrate W is rinsed. Thus, the cleaning liquid L2 remaining on the substrate W is washed away. The rinse liquid L3 supplied onto the substrate W is drained into the drain duct 581.

[Plating Liquid Accumulating Process]

Subsequently, as a plating liquid accumulating process, the plating liquid L1 is supplied onto to be accumulated on the rinsed substrate W (process S4). In this case, the rotational speed of the substrate W is reduced to be smaller than the rotational speed of the substrate W in the rinsing process. By way of example, the rotational speed of the substrate W may be set to be in the range from 50 rpm to 150 rpm. Accordingly, the plating film P to be described later, which is formed on the substrate W, can be uniformed. Further, in order to increase the accumulation amount of the plating liquid L1, the rotation of the substrate W may be stopped.

Then, as depicted in FIG. 5B, the plating liquid L1 is discharged onto the top surface of the substrate W from the plating liquid nozzle 531. The discharged plating liquid L1 stays on the top surface of the substrate W due to a surface tension. Accordingly, the plating liquid L1 is accumulated on the top surface of the substrate W, and a layer (a so-called puddle) of the plating liquid L1 is formed thereon. Some of the plating liquid L1 flows off the top surface of the substrate W to be drained out through the drain duct 581. After a preset amount of the plating liquid L1 is discharged from the plating liquid nozzle 531, the discharge of the plating liquid L1 is stopped.

Then, the nozzle arm 56 located at the discharge position is moved to the retreat position.

[Plating Liquid Heating Process]

Next, as a plating liquid heating process, the plating liquid L1 accumulated on the substrate W is heated. This plating liquid heating process includes a covering process of covering the substrate W with the cover body 6 (process S5), and a heating process of heating the plating liquid L1 while setting the gap between the substrate W and the first ceiling plate 611 to the first gap g1 (process S6). Further, it is desirable to maintain the rotational speed of the substrate W in the heating process equal to the rotational speed in the plating liquid accumulating process (or equal to stop the rotation of the substrate W). Further, as for the rotational speed of the substrate W in the heating process, the stop of the rotation and rotation at a low speed (for example, 20 rpm) may be repeated. Accordingly, the plating liquid L1 is agitated, so that the plating film P can be formed more uniformly.

<Covering Process of Covering Substrate with Cover Body>

First, the substrate W is covered with the cover body 6 (process S5). In this case, the rotation motor 72 of the cover body moving mechanism 7 is first driven, so that the cover body 6 located at the retreat position (the position indicated by the solid line in FIG. 3) is revolved horizontally to be located at the upper position (the position indicated by the solid line in FIG. 3).

Then, as shown in FIG. 5C, the cylinder 73 of the cover body moving mechanism 7 is driven, so that the cover body 6 located at the upper position is lowered and placed at the first gap position. The gap between the substrate W and the first ceiling plate 611 of the cover body 6 becomes the first gap g1, and the sidewall portion 62 of the cover body 6 is placed near the outer periphery of the substrate W. In the present exemplary embodiment, the lower end 621 of the sidewall portion 62 of the cover body 6 is located at a position lower than the bottom surface of the substrate W. In this way, the substrate W is covered by the cover body 6, and a space around the substrate W is closed. At this time, when the cover body is lowered from the upper position to the first gap position, a descending speed of the cover body is controlled to be reduced as the gap between the cover body and the substrate decreases.

To elaborate, as shown in FIG. 5D, the cover body moving mechanism 7 has the second gap position g2 (for example, a position of 30 mm from the front surface of the substrate W) between the first gap position (for example, a position 5 mm from the front surface of the substrate W) and the upper position of the cover body. The descending speed of the cover body 6 is controlled to slow down such that a second descending speed (e.g., 30 mm/sec) from the second gap position g2 to the first gap position becomes lower than a first descending speed (e.g., 75 mm/sec) from the upper position to the second gap position g2. Accordingly, the cover body 6 can be brought close to the vicinity of the substrate W in a short time without spilling the plating liquid L1 on the substrate W. Accordingly, the temperature of the plating liquid L1 on the substrate W is increased rapidly, so that a processing time can be shortened and the liquid processing can be uniformed within the surface of the substrate W.

<Heating Process>

Subsequently, the plating liquid L1 accumulated on the substrate W is heated (process S6). The heating of the plating liquid L1 is performed for a predetermined time period which is set to allow the temperature of the plating liquid L1 to reach a preset temperature. If the temperature of the plating liquid L1 is raised up to a temperature where a component of the plating liquid L1 is precipitated, the component of the plating liquid L1 is precipitated on the top surface of the substrate W, so that the plating film P begins to be formed.

Meanwhile, in this heating process, a reaction gas (hydrogen or the like) is generated from the plating liquid L1 with the growth of the plating film.

The reaction gas generated from the plating liquid L1 stays gradually between the substrate W and the cover body 6, so a concentration of the reaction gas in the central portion of the substrate W increases in the surface of the substrate W. In the surface of the substrate W, if the concentration of the reaction gas in the plating liquid L1 W increases in the central portion of the substrate, the precipitation of the plating component is accelerated thereat, so that the plating film on the central portion of the substrate W becomes thick, whereas the plating film on the outer periphery of the substrate W becomes thin. As a result, the plating film is formed on the substrate W in a non-uniform manner.

However, according to the plating device 5 of the present exemplary embodiment to be described below, a gas exhausting operation is performed in the heating process. The gas exhausting operation is an operation of pushing out the reaction gas staying between the cover body 6 and the substrate W by vertically moving either one of at least the cover body moving mechanism 7 configured to move the cover body 6 and the substrate holder elevating mechanism (not shown) configured to move the substrate holder 52 up and down.

In the heating process, by vertically moving either one of at least the cover body moving mechanism 7 and the substrate holder elevating mechanism, the concentration of the reaction gas staying between the substrate W and the cover body 6 can be dispersed. Accordingly, the increase of the concentration of the reaction gas in the central portion of the substrate W can be suppressed.

Thus, in the surface of the substrate W, the precipitation of the plating component can be performed uniformly, so that the plating film can be formed in the uniform manner.

Here, the gas exhausting operation will be described in detail. In the gas exhausting operation, the cylinder 73 of the cover body moving mechanism 7 is moved from the state in which the cover body 6 is located at the first gap position g1, as shown in FIG. 5C, to locate the cover body 6 at a third gap position g3 (for example, a position of 10 mm apart from the front surface of the substrate W), as illustrated in FIG. 5E. Then, the cylinder 73 of the cover body moving mechanism 7 is driven again to move the cover body 6 from the third gap position g3 to the first gap position g1. At this time, an ascending/descending speed of the cover body 6 is set to be, for example, 70 mm/sec.

In this way, by moving the cover body 6 up and down, the reaction gas staying between the substrate W and the cover body 6 is dispersed, so that the increase of the concentration of the reaction gas in the central portion of the substrate W can be suppressed. Therefore, in the surface of the substrate W, the precipitation of the plating component can be performed uniformly, and the uniform plating film can be formed.

Further, the gas exhausting operation may be performed multiple times in the process of heating the plating liquid L1 on the substrate W. The uniformity of the plating film on the substrate W can be improved by increasing the repetition number of the gas exhausting operation based on a characteristic of the plating liquid L1 or a required thickness of the plating film.

In addition, the gas exhausting operation may be performed such that the substrate W is not exposed between the bottom surface of the ceiling portion 61 and the lower end 621 of the sidewall portion 62. Accordingly, the exposure of the front surface of the substrate W to the atmosphere outside the cover body 6 can be suppressed, so that the plating film on the substrate W can be suppressed from being oxidized.

<Cover Body Retreating Process>

Upon the completion of the heating process, the cover body moving mechanism 7 is driven to locate the cover body 6 at the retreat position (process S7). In this case, the cylinder 73 of the cover body moving mechanism 7 is first driven to raise the cover body 6 located at the second gap position to the upper position. Then, the rotation motor 72 of the cover body moving mechanism 7 is driven, allowing the cover body 6 located at the upper position to be revolved horizontally and located at the retreat position.

When the cover body 6 is raised from the first gap position, the supply amount of the air from the fan filter unit 59 is increased to be returned to the supply amount of the air in the plating liquid accumulating process (process S4). Accordingly, the flow rate of the air flowing around the substrate W is increased, so that the gas vaporized from the plating liquid L1 can be suppressed from rising and diffusing.

In this way, the plating liquid heating process (processes S5 and S6) for the substrate W is completed.

[Substrate Rinsing Process]

Subsequently, the substrate after being subjected to the plating liquid heating process is rinsed (process S8). In this case, the rotational speed of the substrate W is first increased to be higher than the rotational speed in the plating processing. By way of example, the substrate W is rotated at the same rotational speed as that in the substrate rinsing process (process S3) prior to the plating processing. Next, the rinse liquid nozzle 551 positioned at the retreat position is moved to the discharge position. Then, the rinse liquid L3 is supplied from the rinse liquid nozzle 551 onto the substrate W being rotated, so that the front surface of the substrate W is rinsed. As a consequence, the plating liquid L1 left on the substrate W is washed away.

[Substrate Drying Process]

Thereafter, the rinsed substrate W is subjected to a drying processing (process S9). In this case, the rotational speed of the substrate W is increased to be higher than the rotational speed in the substrate rinsing process (process S8), for example, so that the substrate W is rotated at a high speed. Accordingly, the rinse liquid L3 remaining on the substrate W is removed by being scattered off, and the substrate W having the plating film P formed thereon is obtained, as shown in FIG. 5F. Here, the drying of the substrate W may be accelerated by discharging an inert gas such as a nitrogen (N₂) gas to the substrate W.

[Substrate Taking-Out Process]

Then, the substrate W is taken out from the substrate holder 52, and carried out of the plating device 5 (process S10).

In this way, the series of processes S1 to S10 of the plating method for the substrate W using the plating apparatus 1 are completed.

As stated above, according to the apparatus and method described above, by moving either one of at least the cover body 6 and the substrate holder 52 vertically in the middle of heating the plating liquid L1, the reaction gas staying between the substrate W and the cover body 6 is dispersed. Thus, it is possible to suppress the increase of the concentration of the reaction gas in the central portion of the substrate W.

Accordingly, within the surface of the substrate W, the precipitation of the plating component can be performed uniformly, and the uniform plating film can be formed

In addition, the gas exhausting operation may be performed multiple times while heating the plating liquid L1 on the substrate W. By increasing the repetition number of the gas exhausting operation in consideration of the characteristic of the plating liquid L1 or the required thickness of the plating film, the uniformity of the plating film on the substrate W can be improved.

Furthermore, the gas exhausting operation may be performed such that the substrate W is not exposed between the bottom surface of the ceiling portion 61 and the lower end 621 of the sidewall portion 62. Accordingly, it is possible to suppress the front surface of the substrate W from being exposed to the atmosphere outside the cover body 6, so that the oxidation of the plating film on the substrate W can be suppressed.

The above exemplary embodiment has been described for the example where the plating liquid L1 supplied on the substrate W is heated by the heater 63 provided in the cover body 6. However, instead of providing the heater in the cover body 6, a heater (not shown) may be provided inside the substrate holder 52 to heat the plating liquid L1 on the substrate W. Alternatively, it may also be possible to provide heaters in both the cover body 6 and the substrate holder 52.

In addition, in the above-described exemplary embodiment, a second heater (not shown) may be provided in the sidewall portion 62 of the cover body 6. In this configuration, the temperature rise of the plating liquid L1 on the substrate W can be accelerated.

It will be appreciated that the present disclosure is not limited to the above-described exemplary embodiments and modification examples, and that various modifications may be made without departing from the scope of the present disclosure. Furthermore, various other exemplary embodiments may be conceived by appropriately combining the constituent components disclosed in the above-described exemplary embodiments and modification examples. Some components may be deleted from all the constituent components shown in the exemplary embodiments and modification examples. In addition, the constituent components disclosed in the different exemplary embodiments and modification examples may be appropriately combined.

### EXPLANATION OF CODES

1: Plating apparatus
3: Controller
31: Recording medium
52: Substrate holder
53: Plating liquid supply
531: Plating liquid nozzle
59: Fan filter unit
6: Cover body
61: Ceiling portion
611: First ceiling plate
612: Second ceiling plate
62: Sidewall portion
621: Lower end
63: Heater
631: Inner heater
632: Outer heater
633: Intermediate heater
64: Cover body cover
73: Cylinder
L1: Plating liquid

1. A substrate liquid processing method of performing a liquid processing on a substrate by supplying a plating liquid onto the substrate, the substrate liquid processing method comprising:
holding the substrate with a substrate holder;
supplying the plating liquid onto a top surface of the substrate;
covering the substrate with a cover body disposed above the held substrate, the cover body having a ceiling portion; and
heating the plating liquid on the substrate by a heating unit provided in either one of at least the cover body and the substrate holder, in a state that the substrate is covered with the cover body,
wherein a gas exhausting operation of pushing out a reaction gas staying between the cover body and the substrate by moving either one of at least the cover body and the substrate holder vertically is performed in the heating of the plating liquid.

2. The substrate liquid processing method of claim 1,
wherein the gas exhausting operation is performed multiple times in the heating of the plating liquid.

3. The substrate liquid processing method of claim 1,
wherein the cover body comprises a sidewall portion extending downwards from the ceiling portion, and
the gas exhausting operation is performed such that the substrate is not exposed between a bottom surface of the ceiling portion and a lower end of the sidewall portion.

4. A substrate liquid processing apparatus configured to perform a liquid processing on a substrate by supplying a plating liquid onto the substrate, the substrate liquid processing apparatus comprising:
a substrate holder configured to hold the substrate;
a substrate holder elevating mechanism configured to move the substrate holder up and down;
a plating liquid supply configured to supply the plating liquid onto a top surface of the substrate held by the substrate holder;
a cover body disposed above the substrate and configured to cover the substrate held by the substrate holder, the cover body having a ceiling portion equal to or larger than the substrate in size;
a cover body moving mechanism connected to the cover body and configured to move the cover body up and down;
a heating unit provided in either one of at least the substrate holder and the cover body; and
a controller configured to output a control signal such that holding the substrate with the substrate holder; supplying the plating liquid onto the top surface of the substrate; covering the substrate with the cover body; and heating the plating liquid on the substrate by the heating unit in a state that the substrate is covered with the cover body are performed,
wherein the controller outputs a control signal such that a gas exhausting operation of pushing out a reaction gas staying between the cover body and the substrate by moving either one of at least the cover body moving mechanism of the cover body and the substrate holder elevating mechanism of the substrate holder vertically is performed in the heating of the plating liquid on the substrate.

5. The substrate liquid processing apparatus of claim 4,
wherein the gas exhausting operation is performed multiple times in the heating of the plating liquid on the substrate.

6. The substrate liquid processing apparatus of claim 4,
wherein the cover body comprises a sidewall portion extending downwards from the ceiling portion, and
the gas exhausting operation is performed such that the substrate is not exposed between a bottom surface of the ceiling portion and a lower end of the sidewall portion.
